(19) United States
(12) Patent Application Publication
(10) Pub. No.: US 2025/0118639 A1
(43) Pub. Date: Apr. 10, 2025

(54) SEMICONDUCTOR PACKAGE

(71) Applicant: Samsung Electronics Co., Ltd., Suwon-si (KR)

(72) Inventors: Hyunjo KIM, Suwon-si (KR); Junhyeong PARK, Suwon-si (KR); Sunhyung KIM, Suwon-si (KR); Jieun PARK, Suwon-si (KR); Jihye SHIM, Suwon-si (KR); Yuseon HEO, Suwon-si (KR)

(73) Assignee: Samsung Electronics Co., Ltd., Suwon-si (KR)

(21) Appl. No.: 18/672,349

(22) Filed: May 23, 2024

(30) Foreign Application Priority Data
Oct. 5, 2023 (KR) 10-2023-0132555
Nov. 3, 2023 (KR) 10-2023-0150668

(51) Int. Cl. H01L 23/498; H01L 21/48; H01L 21/56; H01L 23/00; H01L 23/31

(52) U.S. Cl. CPC H01L 23/49811; H01L 21/4853; H01L 21/4857; H01L 21/563; H01L 23/3107; H01L 23/49822; H01L 24/16; H01L 2224/16227

(57) ABSTRACT

A semiconductor package includes a first redistribution structure including upper pads; a semiconductor chip disposed on the first redistribution structure; an encapsulant on the first redistribution structure and surrounding the semiconductor chip; a second redistribution structure disposed on the encapsulant and including an upper redistribution layer; a plurality of posts penetrating the encapsulant and electrically connecting the upper pads of the first redistribution structure to the upper redistribution layer of the second redistribution structure; metal layers between the upper pads and the plurality of posts and having an upper surface having a first step difference with an upper surface of an edge of the upper pads; and a seed layer between the metal layers and the plurality of posts.

### CROSS-REFERENCE TO RELATED APPLICATION(S)

This application claims benefit of priority to Korean Patent Application No. 10-2023-0150668 filed on Nov. 3, 2023 and Korean Patent Application No. 10-2023-0132555 filed on Oct. 5, 2023 in the Korean Intellectual Property Office, the disclosures of which are incorporated herein by reference in their entirety.

### BACKGROUND

Example embodiments of inventive concepts relate to a semiconductor package.

Recently, high reliability of a semiconductor package installed in electronic devices has been sought after. Accordingly, development of a semiconductor package having improved reliability by securing reliability of conductive posts has been conducted.

### SUMMARY

Example embodiments of inventive concepts relate to a semiconductor package having improved reliability.

According to example embodiments of inventive concepts, a semiconductor package includes a first redistribution structure including upper pads; a semiconductor chip on the first redistribution structure; an encapsulant surrounding the semiconductor chip on the first redistribution structure; a second redistribution structure disposed on the encapsulant and including an upper redistribution layer; a plurality of posts penetrating the encapsulant and electrically connecting the upper pads of the first redistribution structure to the upper redistribution layer of the second redistribution structure; and a metal layer between the upper pads and the plurality of posts and having an upper surface having a first step difference with an upper surface of an edge of the upper pads; a seed layer disposed between the metal layers and the plurality of posts.

According to example embodiments of inventive concepts, a semiconductor package includes a first redistribution structure including upper pads; a semiconductor chip on the first redistribution structure; an encapsulant on the first redistribution structure and surrounding the semiconductor chip; a second redistribution structure disposed on the encapsulant and including an upper redistribution layer; a plurality of posts penetrating the encapsulant and electrically connecting the upper pads of the first redistribution structure to the upper redistribution layer of the second redistribution structure; and a metal layers between the upper pads and the plurality of posts, and exposing an upper surface of an edge of the upper pads and a lower surface of an edge of the plurality of posts.

According to example embodiments of inventive concepts, a method of manufacturing a semiconductor package includes forming a first redistribution structure including an upper pad having a first width; forming a metal layer on the upper pad, the metal layer having a second width smaller than the first width; forming a post on the metal layer, the post having a width greater than the second width; forming a semiconductor chip on the first redistribution structure, the semiconductor chip electrically connected to at least a portion of the upper pad; forming an encapsulant on the first redistribution structure, the encapsulant at least partially surrounding the semiconductor chip and the post; and forming a second redistribution structure on the encapsulant.

### BRIEF DESCRIPTION OF DRAWINGS

The above and other aspects, features, and advantages of the inventive concepts will be more clearly understood from the following detailed description, taken in combination with the accompanying drawings, in which:

FIG. 1 is a cross-sectional diagram illustrating a semiconductor package according to example embodiments of inventive concepts;

FIG. 2 is an enlarged diagram illustrating a portion of a semiconductor package according to example embodiments of inventive concepts;

FIG. 3 is a plan diagram illustrating a semiconductor package according to example embodiments of inventive concepts;

FIG. 4 is an enlarged diagram illustrating a portion of a semiconductor package according to example embodiments of inventive concepts;

FIG. 5 is a cross-sectional diagram illustrating a semiconductor package according to example embodiments of inventive concepts;

FIG. 6 is a cross-sectional diagram illustrating a semiconductor package according to example embodiments of inventive concepts;

FIG. 7 is a cross-sectional diagram illustrating a semiconductor package according to example embodiments of inventive concepts;

FIG. 8 is a flowchart illustrating processes of a method of manufacturing a semiconductor package in order according to example embodiments of inventive concepts;

FIGS. 9A to 9L are cross-sectional diagrams illustrating a method of manufacturing a semiconductor package in order according to example embodiments of the present disclosure;

FIG. 10 is a flowchart illustrating processes of a method of manufacturing a semiconductor package in order according to example embodiments of inventive concepts;

FIGS. 11A to 11F are cross-sectional diagrams illustrating a method of manufacturing a semiconductor package in order according to example embodiments of the inventive concepts;

FIG. 12 is a flowchart illustrating processes of a method of manufacturing a semiconductor package in order according to example embodiments of inventive concepts; and

FIGS. 13A to 13D are cross-sectional diagrams illustrating a method of manufacturing a semiconductor package in order according to example embodiments of inventive concepts.

### DETAILED DESCRIPTION

Hereinafter, embodiments of the inventive concepts will be described as follows with reference to the accompanying drawings.

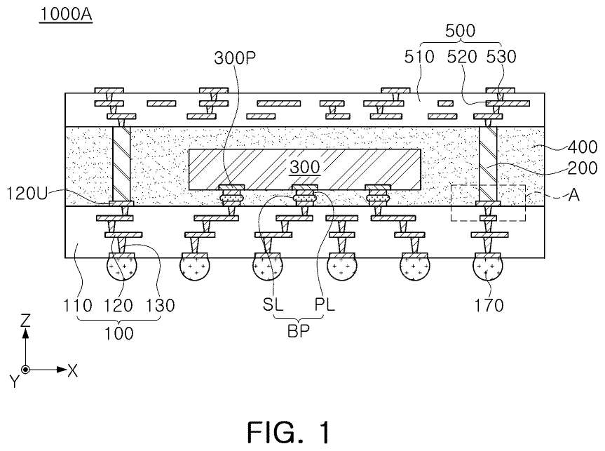

FIG. 1 is a cross-sectional diagram illustrating a semiconductor package 1000A according to some example embodiments.

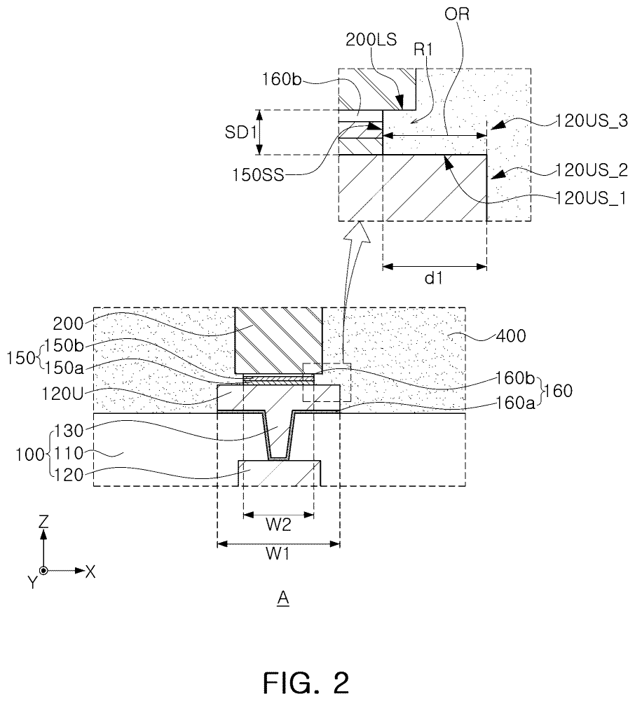

FIG. 2 is an enlarged diagram illustrating region “A” of a semiconductor package according to some example embodiments.

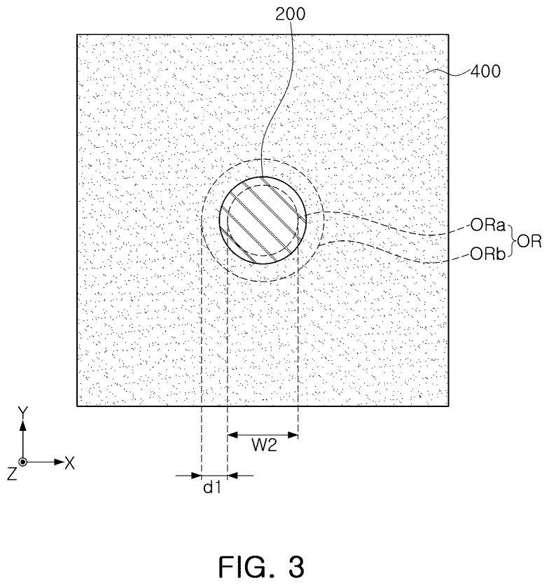

FIG. 3 is a plan diagram illustrating region “A” of a semiconductor package according to some example embodiments.

Referring to FIGS. 1, the semiconductor package 1000A in some example embodiments may include a lower redistribution structure 100, a plurality of posts 200, a lower chip structure 300, and an encapsulant 400. In some example embodiments, the semiconductor package 1000A may further include an upper redistribution structure 500.

Referring to FIGS. 2 and 3, according to some example embodiments, a metal layer 150 may be disposed on an upper pad 120U, and the post 150 may be disposed on the metal layer 150. The upper pad 120U may have (for example, define or at least partially define) a step difference (for example, a level difference or a height difference) with the upper pad 120U, such that an open region OR may be formed (for example, defined or at least partially defined) on an upper surface of an edge of the upper pad 120U, accordingly providing a semiconductor package, such as 1000A shown in FIGS. 1 to 3, including the post 200 disposed on the metal layer and having improved reliability.

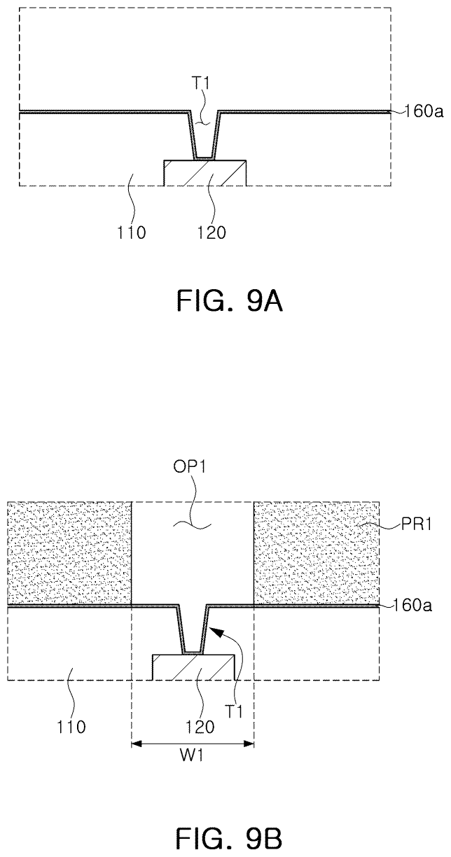

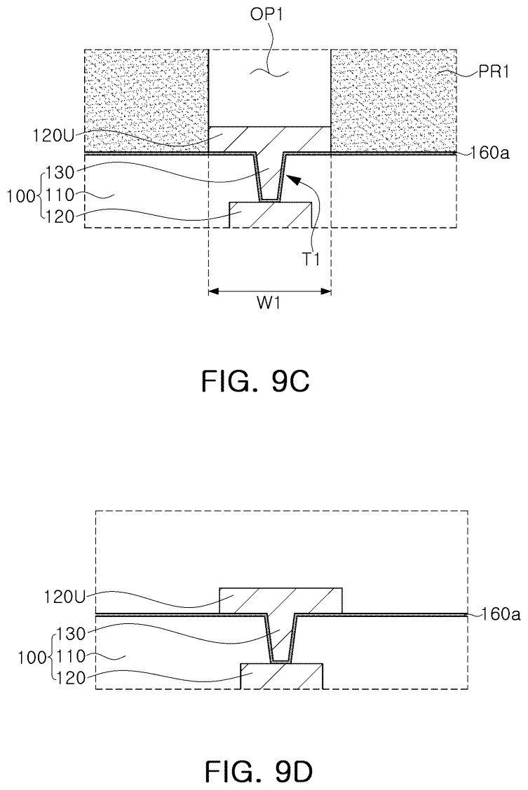

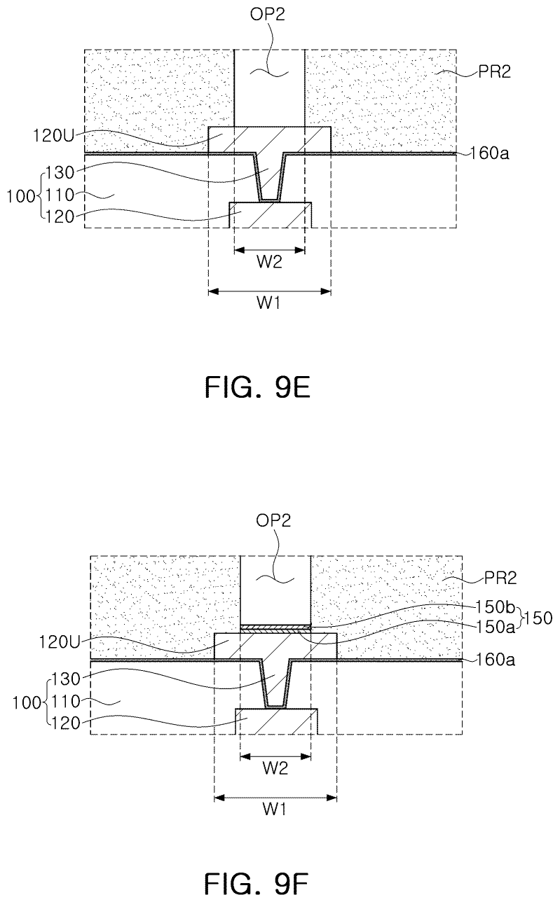

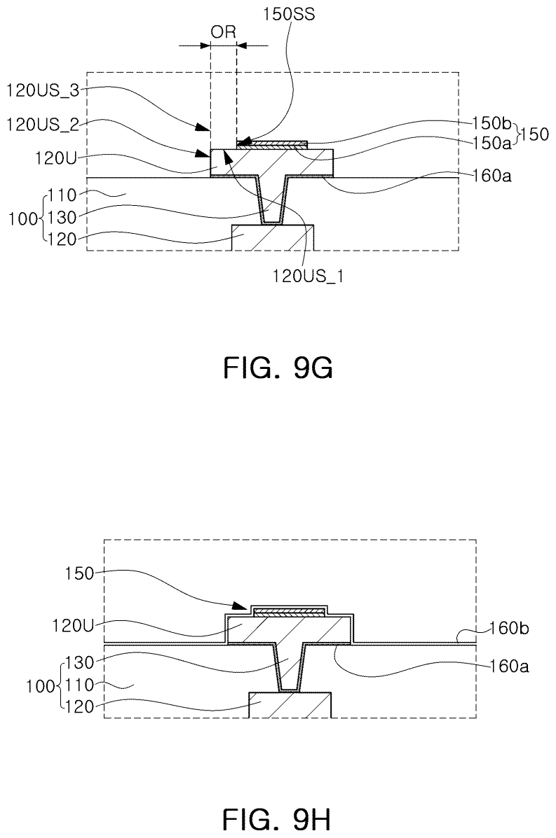

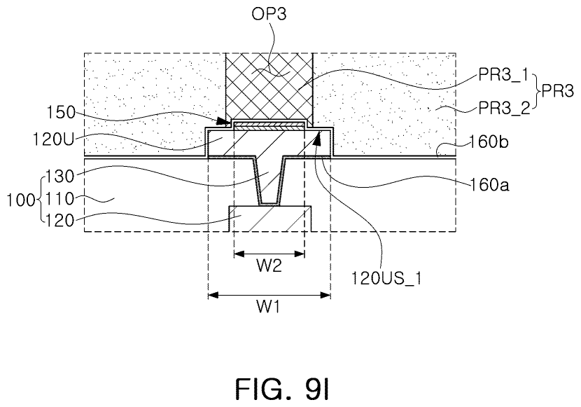

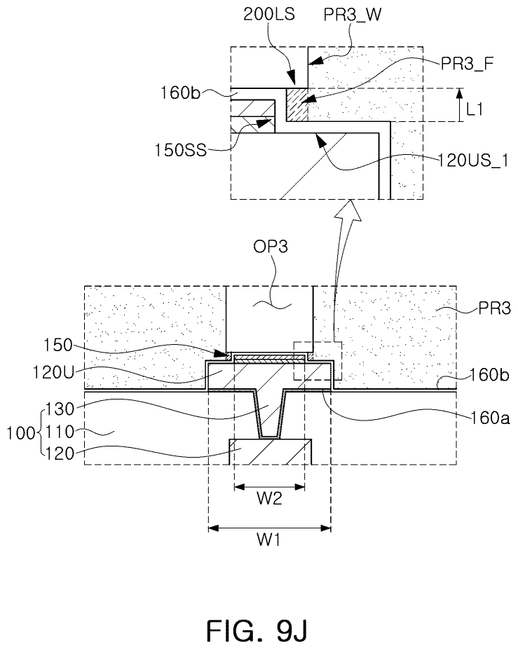

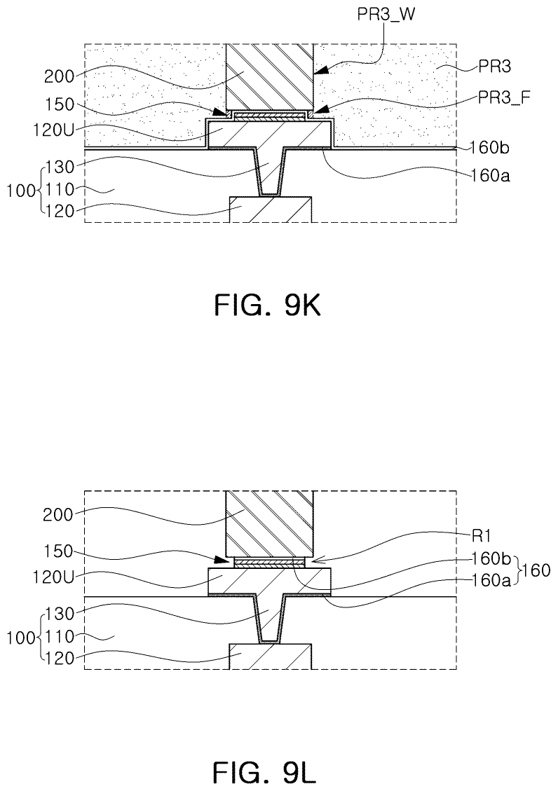

For example, in forming an opening OP penetrating a photoresist layer PR to dispose the post 200 on the metal layer 150, a residue RD separated from a side lower portion of the photoresist layer PR may be disposed in the open region OR formed by the step difference mentioned above, such that reduction of reliability of the post 200 grown (and/or growing) from a metal seed layer 160 on the metal layer 150 due to residue RD may be reduced or prevented (see, e.g., FIGS. 9J and 9K).

Hereinafter, components will be described in greater detail with reference to the drawings.

The lower chip structure 300 may be disposed on the lower redistribution structure 100 and may include first connection terminals 300P electrically connected to lower redistribution layer 120. The first connection terminals 300P may be connected to the lower redistribution layer 120 through the connection bumps BP disposed between the lower chip structure 300 and the lower redistribution structure 100. The connection bumps BP may include a pillar portion PL in contact with the first connection terminals 300P and a solder portion SL disposed below the pillar portion PL. The pillar portion PL may include, for example, copper (Cu) or an alloy of copper (Cu), and the solder portion SL may include, for example, a metal having a low melting point, for example, tin (Sn) or an alloy including tin (Sn), but example embodiments are not limited thereto. In some example embodiments, the connection bumps BP may include only one of the pillar portion PL and the solder portion SL.

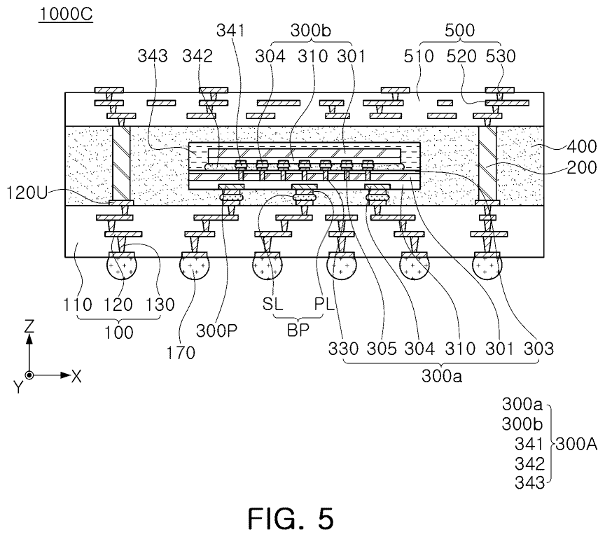

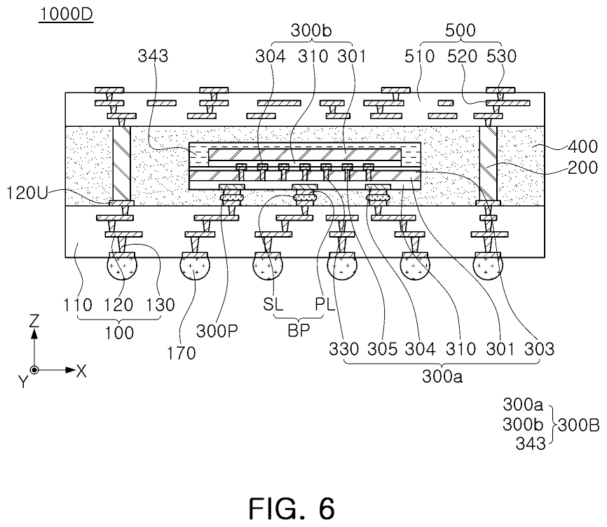

The lower chip structure 300 may include, for example, a semiconductor wafer and/or an integrated circuit (IC) formed of, for example, semiconductor elements such as silicon and/or germanium, and/or a compound semiconductor such as, for example, silicon carbide (SiC), gallium arsenide (GaAs), indium arsenide (InAs), and indium phosphide (InP), BEENT. The lower chip structure 300 may be or include a bare semiconductor chip without a separate bump or interconnection layer, but example embodiments are not limited thereto, and the lower chip structure 300 may be configured as, for example, a packaged type semiconductor chip. The integrated circuit may be implemented as or include, for example, a logic circuit such as a central processor (CPU), graphics processor (GPU), field programmable gate array (FPGA), application processor (AP), digital signal processor, encryption processor, microprocessor, microcontroller, analog-to-digital converter, an application-specific IC (ASIC), and/or a memory circuit (or “memory chip”) including a volatile memory, such as dynamic RAM (DRAM) and/or static RAM (SRAM), and/or a non-volatile memory such as phase change RAM (PRAM), magnetic RAM (MRAM), resistive RAM (RRAM), and/or flash memory, but example embodiments are not limited thereto. In some example embodiments, the lower chip structure 300 may be configured as or include a package structure including a plurality of semiconductor chips, which will be described later with reference to FIGS. 5 and 6.

The lower redistribution structure 100 (or ‘first redistribution structure’) may be, for example, configured as a support substrate on which the lower chip structure 300 is mounted, and may, for example, transmit or be configured to a signal or signals from the lower chip structure 300 disposed thereon, to an external entity, and may additionally or alternatively transmit or be configured to transmit signals and/or power from an external entity to the lower chip structure 300. The lower redistribution structure 100 may be, for example, configured as or include a substrate for a semiconductor package including, for example, a printed circuit board (PCB), ceramic substrate, glass substrate, tape interconnection substrate, and/or the like. For example, the lower redistribution structure 100 may be configured as a double-sided printed circuit board (double-sided PCB) or a multilayer printed circuit board (multilayer PCB), but example embodiments are not limited thereto.

The lower redistribution structure 100 may include a lower insulating layer 110, lower redistribution layers 120, and lower redistribution via s130.

The lower insulating layer 110 may include, for example, an insulating resin. The insulating resin may include a thermosetting resin such as an epoxy resin, a thermoplastic resin such as polyimide, and/or a resin impregnated with an inorganic filler, such as prepreg, Ajinomoto Build-up Film (ABF), FR-4, and bismaleimide-triazine (BT), but example embodiments are not limited thereto. For example, the lower insulating layer 120 may include a photosensitive resin such as, for example, a photo-imageable dielectric (PID), but example embodiments are not limited thereto. The lower insulating layer 120 may include, for example, a plurality of insulating layers (not illustrated) stacked in a vertical direction. Depending on process, boundaries between the plurality of insulating layers (not illustrated) may or may not be indistinct or substantially indistinct.

The lower redistribution layers 120 may be disposed on and/or in the insulating layer 110. The lower redistribution layers 120 may include, for example, copper (Cu), aluminum (Al), silver (Ag), tin (Sn), gold (Au), nickel (Ni), lead (Pb), titanium (Ti), or a metal including an alloy or alloys thereof, but example embodiments are not limited thereto. The lower redistribution layer 120 may perform and/or be configured to perform various functions depending on design. For example, lower redistribution layers 120 may include a ground pattern, a power pattern, and/or a signal pattern. Here, the signal pattern may be defined as a transmission path for various signals, such as, for example, a data signal other than a ground patterns, a power pattern, or the like. The lower redistribution layers 120 may include more or fewer redistribution layers than the illustrated in the drawings. The lower redistribution layers 120 may include upper pads 120U at an upper portion of the lower redistribution structure 100. The upper pads 120U may be electrically connected to connection terminals 300P of the plurality of posts 200 and the lower chip structure 300.

The lower redistribution via 130 may extend vertically in the lower insulating layer 110 and may be electrically connected to the lower redistribution layers 120. For example, individual vias of lower redistribution via 130 may interconnect individual layers of lower redistribution layers 120 that are located at different levels (for example, vertically different levels). The lower redistribution via 130 may include, for example, one or more of a signal via, a ground via, and/or a power via, but example embodiments are not limited thereto. The lower redistribution via 130 may include, for example, at least copper (Cu), aluminum (Al), silver (Ag), tin (Sn), gold (Au), nickel (Ni), lead (Pb), titanium (Ti), or a metal material including an alloy or alloys thereof, but example embodiments are not limited thereto. The lower redistribution via 130 may be, for example, a filled via, for example, a via in which a metal material fills or is filled in the via hole, or, for example, a conformal via, for example, a via in which a metal material extends along an inner wall of the via hole.

The external connection terminals 170 may be disposed below the lower redistribution structure 100. The external connection terminals 170 may be, for example, electrically connected to the lower redistribution layer 120. The semiconductor package 1000A may be connected to external devices such as, for example, a module substrate and/or a system board, through external connection terminals 170. In some example embodiments, the external connection terminals 170 may include, for example, a combination of pillar (and/or underbump metal) and ball, but example embodiments are not limited thereto. The pillar may include, for example, copper (Cu) or an alloy or alloys of copper (Cu), and the ball may include, for example, a low melting point metal, for example, tin (Sn) or an alloy or allows including tin (Sn) (for example, Sn—Ag—Cu) but example embodiments are not limited thereto. In some example embodiments, the external connection terminals 170 may include only one of a pillar or a ball. In some example embodiments, a resist layer protecting and/or configured to protect the external connection terminals 170 from, for example, physical and/or chemical damage may be formed on a lower surface of the lower redistribution structure 100.

Referring to FIG. 2, metal layer 150, which may include multiple metal layers that may be vertically stacked, may be disposed on the upper pad 120U. For example, the metal layers 150 may include a first metal layer 150a and a second metal layer 150b. The first metal layer 150a may include, for example, a metal material or materials including, for example, Ni or Ni alloy, and may be disposed on the upper pad 120U using, for example, an electrolytic plating method or an electroless plating method, but example embodiments are not limited thereto. The second metal layer 150b may include, for example, a metal material or materials such as, for example, Au and/or Pd, and may be disposed on the first metal layer 150a using, for example, the same method as used to dispose the first metal layer 150a, but example embodiments are not limited thereto. For example, the first metal layer 150a may function or be configured to function as a diffusion barrier reducing or preventing growth of a compound between the post 200, disposed on the first metal layer 150a, and the upper pad 120U, disposed below the first metal layer 150a.

The metal layers 150 may be disposed on the upper pad 120U to define (for example, at least partially define) a predetermined or, alternatively, a desired open region OR exposing the upper surface 120US_1 of an edge of the upper pad. In more detail, the metal layers 150 may have a horizontal width smaller than a horizontal width of the upper pad 120U. For example, the upper pad 120U may have a first horizontal width W1 (or “first width”), and the metal layers 150 may have a second horizontal width W2 (or “second width”) smaller than the first horizontal width W1, but example embodiments are not limited thereto. Referring to the plan diagram of FIG. 3, as the upper pad 120U and the metal layers 150 may have different widths, an open region OR may be formed (for example, defined or at least partially defined) on the upper surface 120US_1 (see FIG. 3). Accordingly, an upper surface of the metal layers 150 may have (for example, define or at least partially define) a first step difference SD1 with the upper surface 120US_1 of an edge of the upper pad on the upper pad 120U. The first step difference SDI may be a level difference or height difference between the upper surface of the metal layers 150 and the upper surface 120US_1 of the edge of the upper pad. In some example embodiments, a metal seed layer 160 may be further disposed on the metal layers 150. For example,, the first step difference SDI may be a level difference or height difference between an upper surface of the metal seed layer 160 disposed on the metal layers 150 and the upper surface 120US_1 of the edge of the upper pad.

Referring to FIG. 2, the open region OR may be defined (for example, at least partially defined) as or in a region defined (for example, at least partially defined) by a side surface 150SS of the metal layers (or “side surface of metal layers and metal seed layers”) virtual side surface 120US_3 connected to (for example, extending from) the side surface 120US_2 of the upper pad in the vertical direction (Z-direction). The open region OR may have, for example, a donut shape, donut-like shape, or annular shape having an inner portion ORa and an outer portion ORb (see FIG. 3), but example embodiments are not limited thereto. The inner portion

ORa may have, for example, a circular shape having a diameter equal to the second width W2, and the outer portion ORb may be uniformly spaced apart from the inner portion ORa by a first distance d1, but example embodiments are not limited thereto. The first distance d1 may be derived, for example, from a difference between the first horizontal width W1 of the upper pad 120U and the second horizontal width W2 of the metal layers 150. According to some example embodiments, the first distance d1 may be half the value obtained by subtracting the second horizontal width W2 from the first horizontal width W1. The first distance d1 may be, for example, about 10 μm or less, for example, 1 μm or more and 10 μm or less, 1 μm or more and 5 μm or less, 2 μm or more and 5 μm or less, or 2 μm or more and 4 μm or less, but example embodiments are not limited thereto.

A metal seed layer 160 covering at least a portion of a surface of the upper pad 120U and at least a portion of the metal layers 150 may be disposed. The metal seed layer 160 may include, for example, a first metal seed layer 160a and a second metal seed layer 160b. The first metal seed layer 160a may be disposed to cover or at least partially cover a surface of the lower redistribution via 130 and a lower surface of the upper pad 120U. For example, the first metal seed layer 160a may be disposed on at least a portion of the surface of the lower redistribution structure 100 and an upper surface of the interconnection layer 120 to form an lower redistribution via 130 and an upper pad 120U on the interconnection layer 120 using, for example, an electrolytic plating method (see FIG. 9C). The second metal seed layer 160b may be disposed on the metal layer 150. For example, the second metal seed layer 160b may be disposed on the upper surface of the metal layer 150 to form the post 150 on the metal layer 150 (or “second metal layer 150b”) using, for example, electroplating (see FIG. 9H). The metal seed layer 160 may include for example, at least one of copper (Cu) and copper (Cu) alloy, but example embodiments are not limited thereto. The metal seed layer 160 may include, for example, at least one of tin (Sn), indium (In), lead (Pb), zinc (Zn), nickel (Ni), gold (Au), silver (Ag), titanium (Ti), and or alloy thereof, but example embodiments are not limited thereto. Referring to FIGS. 9A and 9H together, the first metal seed layer 160a and the second metal seed layer 160b may each be, for example, formed by physical vapor deposition, but example embodiments are not limited thereto.

The plurality of posts 200 may be disposed around the lower chip structure 300 and may penetrate the encapsulant 400 to electrically connect the lower redistribution layer 120 to the upper redistribution layer 520. One end of a post 200 may be disposed on the upper pad 120U of an upper portion of the lower redistribution structure 100. The other end of the post 200 may extend in a direction perpendicular to an upper surface of the lower redistribution structure 100 (Z-direction). Individual posts of the plurality of posts 200 may have a cylindrical shape, but example embodiments are not limited thereto. Posts of plurality of posts 200 may be spaced apart from the lower chip structure 300 in the horizontal direction (X-direction). The plurality of posts 200 may be electrically connected to the lower redistribution layer 120, and may be electrically connected to the first connection terminals 300P of the lower chip structure through the lower redistribution layer 120.

The plurality of posts 200 may be disposed on an upper surface of the metal seed layer 160 disposed on the metal layer 150. The plurality of posts 200 may have a horizontal width greater than the second horizontal width W2 of the metal layers 150 and smaller than the first horizontal width W1 of the upper pad 120U. Accordingly, in a cross-sectional view, the side surface 200SS of the plurality of posts may be formed to protrude further than the side surface 150SS of the metal layers. Accordingly, at least a portion 200LS of a lower surface of the plurality of posts may be exposed to oppose (for example, face) the upper surface 120US_1 of an edge of the upper pad. Accordingly, the lower surface 200LS of the plurality of posts, the side surface 150SS of the metal layers, and the upper surface 120US_1 of the edge of the upper pad may form (for example, define or at least partially define) a first recessed portion R1. The first recessed portion R1 may be defined as a recessed groove portion (or “first groove portion”) recessed or extending horizontally in a direction from the virtual side surface 120US_3 of the upper pad toward the metal layer 150, for example a central portion of the metal layer 150. A vertical height of the first recessed portion RI may be equal or substantially equal to a size of the first step difference SD1.

The encapsulant 400 surrounding the lower chip structure 300 may be disposed on the lower redistribution structure 100. The encapsulant 400 may protect the lower chip structure 300 from external environments such as physical impacts or moisture. The encapsulant 400 may include, for example, a thermosetting resin such as an epoxy resin, a thermoplastic resin such as polyimide, prepreg, ABF, FR-4, BT, epoxy molding compound (EMC), or the like. The encapsulant 400 may cover a surface of the upper pad 120U, the metal layer 150, and the plurality of posts 200 on the lower redistribution structure 100. At least a portion of the encapsulant 400 may be inserted into the first recessed portion R1. At least a portion of the encapsulant 400 may be in contact with at least a portion of the lower surface 200LS of the plurality of posts in the first recessed portion R1.

The upper redistribution structure 500 (or “second redistribution structure”) may be disposed on the encapsulant 400 and may include an upper insulating layer 510, upper redistribution layers 520, and an upper redistribution via 530.

The upper insulating layer 510 may include a thermosetting resin such as an epoxy resin, a thermoplastic resin such as polyimide, or a resin impregnated with an inorganic filler, or the like., such as prepreg, ABF, FR-4, and BT. For example, the upper insulating layer 510 may include a photosensitive resin such as PID. The upper insulating layer 351 may include a plurality of insulating layers stacked in the vertical direction (Z-direction). Depending on processes, boundaries between the plurality of insulating layers may or may not be distinct.

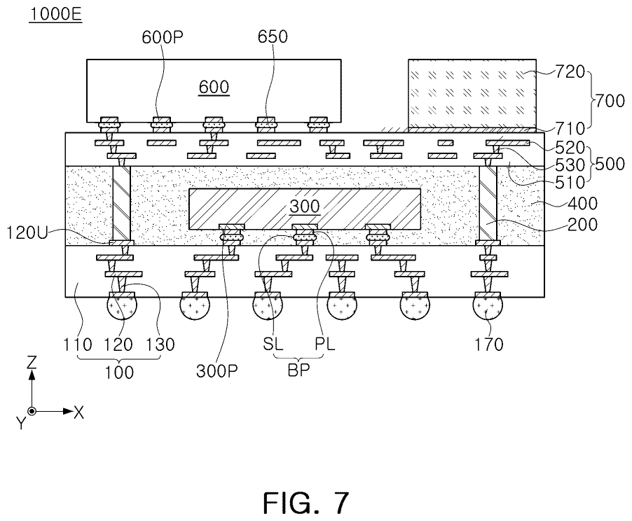

The upper redistribution layer 520 may be disposed on and in the upper insulating layer 510. The upper redistribution layer 520 may redistribute a chip structure mounted on the upper redistribution structure 500, for example, the upper chip structure 200 in FIG. 7. The upper redistribution layer 352 may include a metal, for example, at least one of copper (Cu), aluminum (Al), silver (Ag), tin (Sn), gold (Au), nickel (Ni), lead (Pb), titanium (Ti), or alloy or alloys thereof. The upper redistribution layer 352 may include at least one of a ground pattern, a power pattern, and/or a signal pattern depending on a design. The upper redistribution layer 352 may include more or fewer redistribution layers than the example illustrated in the drawing.

The upper redistribution via 530 may extend in the upper insulating layer 510 and may be electrically connected to the upper redistribution layer 520. For example, the upper redistribution via 530 may interconnect the upper redistribution layers 520 at different levels. The upper redistribution via 530 may include a metal material including, for example, one or more copper (Cu), aluminum (Al), silver (Ag), tin (Sn), gold (Au), nickel (Ni), lead (Pb), titanium (Ti), or alloy or alloys thereof. The upper redistribution via 530 may be, for example, a filled via in which a metal material fills or is filled in a via hole, or a conformal via in which a metal material may extend along an inner wall of the via hole.

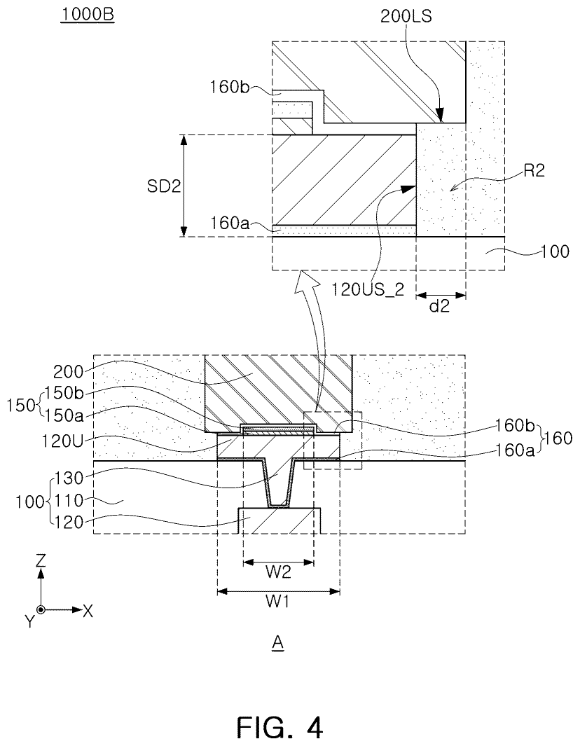

FIG. 4 is an enlarged diagram illustrating a portion of a semiconductor package according to some example embodiments.

Referring to FIG. 4, a plurality of posts 200 may be the same as in FIGS. 1 to 3 except for the configuration in which the plurality of posts 200 may have a horizontal width greater than the first horizontal width W1 of the upper pad 120U.

Referring to FIG. 4, the metal seed layer 160 may cover a surface of the metal layer 150 and the upper surface 120US_1 of an edge of the upper pad. A plurality of posts 200 may be formed on an upper surface of the metal seed layer 160.

The plurality of posts 200 may have a horizontal width greater than the second horizontal width W2 of the metal layers 150 and greater than the first horizontal width W1 of the upper pad 120U. Accordingly, in a cross-sectional view, a side surface 200SS of the post may be formed to protrude further than the side surface 120US_2 of the upper pad. Accordingly, at least a portion 200LS of a lower surface of the post may be exposed to oppose (for example, face) an upper surface of the lower insulation layer 110. Accordingly, the lower surface 200LS of the post, the side surface 120US_2 of the upper pad, and an upper surface of the lower insulating layer 110 may form (for example, define or at least partially define) a second recessed portion R2. The second recessed portion R2 (or “second groove portion”) may be defined as a portion that is recessed in a horizontal direction toward the upper pad 120U, for example a central portion of the upper pad 120U.

The second recessed portion R2 may have a horizontal distance equal to the second distance d2. The second distance d2 may be the same or substantially the same as a first distance d1 described with reference to FIGS. 1 to 3. For example, the second distance d2 may be about 10 μm or less, for example, 1 μm or more and 10 μm or less, 1 μm or more and 5 μm or less, 2 μm or more and 5 μm or less, or 2 μm or more and 4 μm or less, but example embodiments are not limited thereto.

The upper pad 120U may include an upper surface of the lower redistribution structure 100 defining (for example, at least partially defining) a second step difference SD2 with, for example, a bottom surface of first metal seed layer 160a. A vertical height of the second recessed portion R2 may be equal or substantially equal to a size of the second step difference SD2. In some example embodiments, an additional metal seed layer of metal seed layer 160 may be further disposed below the upper pad 120U. In this case, the second step difference SD2 may be defined as a level difference or height difference between an upper surface of the metal seed layer 160 disposed on the first metal seed layer 160a and an upper surface of the lower redistribution structure 100.

The encapsulant 400 may cover a surface of the upper pad 120U and the plurality of posts 200 on the lower redistribution structure 100. At least a portion of the encapsulant 400 may be inserted into the second recessed portion R2. In the second recessed portion R2, at least a portion of the encapsulant 400 may be in contact with at least a portion of the lower surface 200LS of a post 200 post.

FIG. 5 is a cross-sectional diagram illustrating a semiconductor package according to some example embodiments.

Referring to FIG. 5, a semiconductor package 1000C in some example embodiments may be configured the same as or similarly to the example in FIGS. 1 to 3 except for the configuration in which a lower chip structure 300A (or “chip structure”) including the plurality of semiconductor chips 300a and 300b buried therein.

At least a portion of the plurality of semiconductor chips 300a and 300b (for example, “300a”) may include through-vias 330 electrically connecting the plurality of semiconductor chips 300a and 300b to each other. The plurality of semiconductor chips 300a and 300b may, for example, be or include chiplets included in a multi-chip module (MCM). The plurality of semiconductor chips 300a and 300b may, for example, include at least one of a central processor (CPU), graphics processor (GPU), field programmable gate array (FPGA), digital signal processor (DSP), encryption processor, microprocessor, microcontroller, analog-to-digital converter, application-specific semiconductor (ASIC), volatile memory, non-volatile memory, input/output (I/O) circuit, analog circuit, serial-parallel conversion circuit, or the like, but example embodiments are not limited thereto.

The chip structure 300A may include a base chip 300A and at least one stack chip 300b. For example, the base chip 300A may include a processor circuit, and at least one stack chip 300b may include at least one of an input/output circuit for a processor circuit, an analog circuit, a memory circuit, and a serial-to-parallel conversion circuit, but example embodiments are not limited thereto. The number of the base chip 300A and at least one stack chip 300b may be greater than the example illustrated in the drawing. For example, at least one stack chip 300b may include two or more semiconductor chips arranged horizontally and/or vertically on the base chip 300A, but example embodiments are not limited thereto.

The base chip 300A and at least one stack chip 300b may include a substrate 301, an upper protective layer 303, an upper pad 305, a circuit layer 310, a lower pad 304, and/or a through-via 330. The substrate 301 may include, for example, a semiconductor element such as silicon or germanium (Ge), or a compound semiconductor such as silicon carbide (SIC), gallium arsenide (GaAs), indium arsenide (InAs), or indium phosphide (InP), but example embodiments are not limited thereto. The substrate 101 may have or include a silicon on insulator (SOI) structure. The substrate 301 may have a conductive region, for example, a well doped with impurities, or an active surface doped with impurities and an inactive surface. The substrate 301 may include various device isolation structures, such as a shallow trench isolation (STI) structure, but example embodiments are not limited thereto.

The upper protective layer 303 may be formed on an inactive surface of the substrate 301 and may protect the substrate 301. The upper protective layer 303 may be formed of or include an insulating layer such as a silicon oxide film, a silicon nitride film, or a silicon oxynitride film, but a material of the upper protective layer 303 is not limited thereto. For example, the upper protective layer 303 may, for example, be formed of or include a polymer such as polyimide (PI). Although not illustrated in the drawing, a lower protective layer may be further formed on a lower surface of the circuit layer 310.

The upper pad 305 may be disposed on the upper protective layer 303. The upper pad 305 may include, for example, at least one of aluminum (Al), copper (Cu), nickel (Ni), tungsten (W), platinum (Pt), gold (Au), or any alloy thereof. The lower pad 304 may be disposed below the circuit layer 310 and may include a material similar to the upper pad 305. However, the materials of the upper pad 305 and the lower pad 304 are not limited to the materials mentioned above. The lower pad 304 may correspond to the first connection terminals 300P described above.

The circuit layer 310 may be disposed on an active surface of the substrate 301 and may include various types of devices. For example, the circuit layer 310 may include at least one of a FET such as a planar field effect transistor (FET) or FinFET, a memory device such as a flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), and resistive random access memory (RRAM), a logic element such as AND, OR, NOT, and various active and/or passive components such as system large scale integration (LSI), CMOS imaging sensor (CIS), micro-electro-mechanical system (MEMS), but example embodiments are not limited thereto. The circuit layer 310 may include a wiring structure electrically connected to the above-described devices and an interlayer insulating layer surrounding the wiring structure. The interlayer insulating layer may include, for example, silicon oxide or silicon nitride. The wiring structure may include multilayer wirings and/or vertical contacts. The wiring structure may connect devices of the circuit layer 310 to each other, connect devices of the circuit layer 310 to a conductive region of the substrate 101, and/or connect of the circuit layer 310 devices to the through-via 330.

The through-via 330 may penetrate the substrate 301 in the vertical direction (Z-direction) and may provide an electrical path connecting the upper pad 305 and the lower pads 304. The through-via 330 may include a conductive plug and a barrier film surrounding the same. The conductive plug may include, for example, at least one metal, such as tungsten (W), titanium (Ti), aluminum (Al), copper (Cu), or alloy thereof. The conductive plug may be formed by, for example, a plating process, PVD process, or CVD process. The barrier film may include an insulating barrier film and/or a conductive barrier film. The insulating barrier film may be formed of, for example, an oxide film, a nitride film, a carbonization film, a polymer, or a combination thereof. The conductive barrier film may be disposed between the insulating barrier film and the conductive plug. The conductive barrier film may include a metal compound such as, for example, tungsten nitride (WN), titanium nitride (TiN), or tantalum nitride (TaN), or alloy thereof, but example embodiments are not limited thereto. The barrier film may be formed by, for example, a PVD process or CVD process.

The bumps 341 and the adhesive layer 342 may be disposed between the base chip 300A and at least one stack chip 300b. The bumps 341 may electrically connect the base chip 300A to at least one stack chip 300b. The bumps 341 may be formed of, for example, tin (Sn), indium (In), bismuth (Bi), antimony (Sb), copper (Cu), silver (Ag), zinc (Zn), lead (Pb) and/or alloys thereof, and may have a combination of a metal pillar and a solder ball in some example embodiments. The adhesive layer 342 may surround each of the bumps 341 and may bond the base chip 300A to at least one stack chip 300b. The adhesive layer 342 may be formed using a non-conductive film (NCF), but example embodiments are not limited thereto, and the adhesive layer 342 may be formed using any type of insulating film for a heat compression process, for example. In some example embodiments, the adhesive layer 342 may cover at least a portion of a side surface of at least one stack chip 300b, but example embodiments are not limited thereto.

At least one stack chip 300b and a mold 343 surrounding (for example, at least partially surrounding) an outer side surface of the adhesive layer 342 may be disposed on the base chip 300A. The mold 343 may include thermosetting resin such as epoxy resin, thermoplastic resin such as polyimide, prepreg, ABF, FR-4, BT, EMC, or the like, but example embodiments are not limited thereto.

FIG. 6 is a cross-sectional diagram illustrating a semiconductor package according to some example embodiments.

Referring to FIG. 6, a semiconductor package 1000D in some example embodiments may be configured the same as or similar to the example described with reference to FIGS. 1 to 5, other than the configuration in which a lower chip structure (or “chip structure”) 300b in which a base chip 300A and stack chips 300b are directly bonded and/or coupled to each other may be included.

The chip structure 300b may include a base chip 300A, at least one stack chip 300b, and a mold 343. The base chip 300A and at least one stack chip 300b may be directly bonded and coupled to each other without a connection member (for example, solder bump, copper pillar, or the like.). The chip structure 300b may include a bonding surface BS in which an upper surface of the base chip 300A and a lower surface of at least one stack chip 300b may be bonded. The bonding surface BS may be formed by metal bonding and/or dielectric bonding. but example embodiments are not limited thereto. The upper pad 305 of the base chip 300A and the lower pad 304 of the stack chip 300b may, for example, include copper (Cu). The upper protective layer 303 surrounding the upper pad 305 of the base chip 300A and the dielectric layer surrounding the lower pad 304 of the stack chip 300b may include at least one of materials bonded to each other, for example, silicon oxide (SiO), silicon nitride (SiN), and silicon carbonitride (SiCN), but example embodiments are not limited thereto.

FIG. 7 is a cross-sectional diagram illustrating a semiconductor package 1000E according to some example embodiments.

Referring to FIG. 7, the semiconductor package 1000E in some example embodiments may be configured the same as or similar to the example described with reference to FIGS. 1 to 4, other than the configuration in which the upper chip structure 600 and/or the heat dissipation member 700 may be included.

The upper chip structure 600 may be a bare chip or a packaged chip including a logic circuit and/or memory circuit formed thereon. In example embodiments, the upper chip structure 600 may be a package structure in which a plurality of semiconductor chips are mounted on a substrate. The upper chip structure 600 may include a different type of semiconductor chips from those of the lower chip structure 300. For example, the lower chip structure 300 may include a logic chip, and the upper chip structure 600 may include a memory chip, but example embodiments are not limited thereto.

The upper chip structure 600 may be disposed on the upper redistribution structure 500. The upper chip structure 600 may be electrically connected to the lower redistribution layer 120 through the plurality of posts 200. In some example embodiments, the plurality of posts 200 may be arranged in a position overlapping the upper chip structure 600 in the vertical direction (Z-direction). The upper chip structure 600 may include second connection terminals 600P electrically connected to the plurality of posts 200. The second connection terminals 600P may be connected to the plurality of posts 200 through the upper connection bumps 650 disposed between the upper chip structure 600 and the plurality of posts 200. The upper chip structure 600 may be electrically connected to the lower chip structure 300 through the lower redistribution layer 120 and the plurality of posts 200. In example embodiments, an insulating metal layer surrounding the upper connection bumps 6250 may be formed below the upper chip structure 600, but example embodiments are not limited thereto.

The heat dissipation member 700 may be disposed on at least one side of the upper chip structure 600. The heat dissipation member 700 may overlap at least a portion of the lower chip structure 300 in a vertical direction (Z-direction). In some example embodiments, the heat dissipation member 700 may have a shape surrounding (for example, at least partially surrounding) four sides of the upper chip structure 600. The heat dissipation member 700 may help control warpage of the semiconductor package 1000E and may dissipate heat generated from the lower chip structure 600 externally.

The heat dissipation member 700 may include a thermal interface material (TIM) 741, and a heat slug 742 (not shown). The thermal interface material 741 may be in contact with an upper surface of the lower chip structure 300. The thermal interface material 741 may include, for example, thermally conductive adhesive tape, thermally conductive grease, thermally conductive adhesive, or the like. The heat slug 742 may be disposed on the thermal interface material 741. The heat slug 742 may include a material having excellent thermal conductivity, such as, for example, aluminum (Al), gold (Au), silver (Ag), copper (Cu), iron (Fe), graphite, graphene, or the like, but example embodiments are not limited thereto.

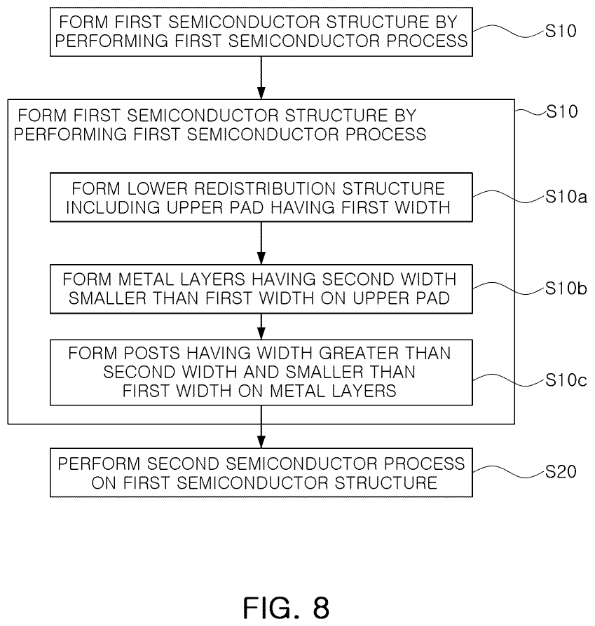

FIG. 8 is a flowchart illustrating processes of a method of manufacturing a semiconductor package according to some example embodiments. FIGS. 9A to 9I are cross-sectional diagrams illustrating a method of manufacturing a semiconductor package according to example embodiments.

Referring to FIGS. 8 and 9A to 9L, a first semiconductor structure may be formed by performing a first semiconductor process (S10). Thereafter, a semiconductor package 1000A may be formed by performing a second semiconductor process on the first semiconductor structure (S20).

Referring to FIGS. 8 and 9A to 9D, a lower redistribution structure 100 including lower insulation layer 110, lower redistribution layer 120, and lower redistribution via 130, and an upper pad 120U having a first width W1 may be formed (S10a).

Referring to FIG. 9A, a trench T1 may be formed in an upper portion of the lower insulation layer 110, and a first metal seed layer 160a covering an internal surface of trench Tl and an upper surface of the lower insulation layer 110 may be formed.

The trench T1 may penetrate at least a portion of an upper portion of the lower insulation layer structure 110, and a portion of an upper surface of the lower redistribution layer 120 may be exposed by the trench T1. The first metal seed layer 160a may be formed to cover a portion of an upper surface of the lower redistribution layer 120 in the trench T1, and may be formed evenly along an internal surface of the trench T1 and an upper surface of the lower insulation layer 110. The first metal seed layer 160a may be formed by, for example, physical vapor deposition.

Referring to FIG. 9B, a first photoresist layer PR1 may be formed on the first metal seed layer 160a, and the first opening OP1 having a first width W1 may be formed.

The first photoresist layer PR1 may include, for example, a photoresist including a photosensitive resin. Here, the first photoresist layer PR1 may be applied on the first metal seed layer 160a by screen printing.

A photomask may be aligned on the first photoresist layer PR1, and using the photomask, the trench T1 may be exposed and the first opening OP1 having the first width W1 may be formed.

Referring to FIG. 9C, an lower redistribution via 130 and an upper pad 120U may be formed on the first metal seed layer 160a in the first opening OP1.

The lower redistribution via 130 may be grown from a portion of the first metal seed layer 130 on a surface of the trench T1 and may fill the trench T1. The upper pad 120U may be grown from a portion of the first metal seed layer 130 on an upper surface of the lower insulating layer and may be formed on the lower chip structure 110 to have a first width W in the first opening OP1. The lower redistribution via 130 and the upper pad 120U may be formed using electrolytic plating. The upper pad 120U may be formed simultaneously with the lower redistribution via 130 and may have, for example, shape that is a continuous with the lower redistribution via 130.

Referring to FIG. 9D, the first photoresist layer PR1 may be removed.

Referring to FIG. 9C and 9D together, the first photoresist layer PR1 may be removed through a first stripping process after electrolytic plating for forming the lower redistribution via 130 and the upper pad 120U is completed. Accordingly, a portion of the surface of the first metal seed layer 160a and a portion of the surface of the upper pad 120U may be exposed.

Referring to FIGS. 8 and 9E to 9G, metal layers 150 having a second width W2 smaller than the first width may be formed on the upper pad 120U (S10b).

Referring to FIG. 9E, a second photoresist layer PR2 may be formed, and a second opening OP2 having a second width W2 may be formed.

The second photoresist layer PR2 may be applied to the partially exposed surface of the first metal seed layer 160a and the upper pad 120U by a first stripping process according to FIG. 9D. Here, the second photoresist layer PR2 may include a photoresist including a photosensitive resin similarly to the first photoresist layer PRI, and may be applied by for example, a screen-printing method.

A photomask may be aligned on the second photoresist layer PR2, and a second opening OP2 having a second width W2 smaller than the first width W1 may be formed using the photomask. A portion of an upper surface of the upper pad 120U may be exposed by the second opening OP2.

Referring to FIG. 9F, a plurality of metal layers 150 may be sequentially formed on a portion of a partially exposed upper surface of the upper pad 120U by the second opening OP2.

In the second opening OP2, a first metal layer 150a may be formed on a portion of the upper surface of the upper pad 120U using, for example, an electrolytic plating method or an electroless plating method, and a second metal layer 150b may be formed on the first metal layer 150a using the same method. The first metal layer 150a may include a metal material including, for example, Ni or a Ni alloy, and the second metal layer 150b may include, for example, a metal material such as Au or Pd, but example embodiments are not limited thereto.

Referring to FIG. 9G, the second photoresist layer PR2 may be removed and a portion of the first metal seed layer 160a may be removed.

Referring to FIG. 9F together, the second photoresist layer PR2 may be removed through a second stripping process after electrolytic plating or electroless plating for forming the plurality of metal layers 150 is completed.

Accordingly, on the upper pad 120U, an open region OR surrounding a side surface 150SS of the metal layers may be formed. As described with reference to FIG. 2, the open region OR may be defined in a range from the side surface 150SS of the metal layers to the virtual side surface 120US_3 connecting the side surface 120US_2 of the upper pad in the vertical direction (Z-direction). Accordingly, the open region OR may expose the upper surface 120US_1 of an edge of the upper pad.

Thereafter, since the upper pad 120U may not be disposed on the first metal seed layer 160a, a portion thereof exposed by the second stripping process may be removed through etching. Accordingly, the first metal seed layer 160a may only remain below the upper pad 120U.

Referring to FIGS. 8 and 9H to 9L, posts 200 having a width greater than a second width W2 and smaller than a first width W1 may be formed on the metal layers 150 (S10c).

Referring to FIG. 9H, after the operation in FIG. 9G, a second metal seed layer 160b may be formed.

The second metal seed layer 160b may be formed along an upper surface of the lower redistribution structure 100 and surfaces of the upper pad 120U and the metal layers 150. The second metal seed layer 160b may be formed by, for example, physical vapor deposition.

Referring to FIG. 9i, a third photoresist layer PR3 may be formed on the second metal seed layer 160b. Thereafter, to form the third opening OP3, an exposure process may be performed on a portion by aligning the photomask on the third photoresist layer PR3.

The third photoresist layer PR3 may include a photoresist including a photosensitive resin. The third photoresist layer PR3 may include a positive photoresist and a negative photoresist, but according to some example embodiments, the third photoresist layer PR3 may include a negative photoresist. Accordingly, using a photomask, an exposure process may be performed only on a portion PR3_2 (or “photosensitive portion”) of the third photoresist layer PR3, other than a portion PR3_1 (or “non-photosensitive portion”) to form third opening OP3, and during a subsequent development process, a third opening OP3 may be formed by removing the non-photoresistive portion PR3_1 (see FIG. 8J).

Meanwhile, the third photoresist layer PR may have a high aspect ratio. Accordingly, a lower portion of a portion (or “sidewall PR3_W of the third photoresist layer”) in which the non-photoresistive portion PR3_1 and the photoresisted portion PR3_2 are in contact with each other may be spaced apart from the photomask, such that the portion may have a relatively lower degree of curing than an upper portion of the sidewall PR3_W of the third photoresist layer.

Referring to FIG. 9J, the third opening OP3 may be formed by developing and removing the non-photoresistive portion PR3_1 according to FIG. 91.

The third opening OP3 may be formed to have a width greater than the second width W2 of the metal layers 150 and smaller than the first width W1 of the upper pad 120U. Accordingly, at least a portion of the upper surface 120US_1 of an edge of the upper pad may be exposed by the third opening OP3.

Here, the lower portion of the sidewall PR3_W of the third photoresist layer may be distanced from the photomask, such that a degree of curing thereof may be low. Accordingly, residue PR3_F may be separated from the lower portion and may be formed along a perimeter of a side lower portion (or “side surface 150SS of metal layers”) of the third opening OP3.

Referring to FIGS. 9F and 9G together, the residue PR3_F may be formed on or in a step difference portion (or “open region OR”) which may be formed (for example, defined or at least partially defined) by forming the metal layers 150 having a second width W2 smaller than the first width on the upper pad 120U having the first width W1. The residue PR3_F may be in contact with a surface of the second metal seed layer 160b in the step difference portion. A level L1 of the portion on which surfaces of the residue PR3_F and the second metal seed layer 160b are in contact with each other may be equal or substantially equal to or lower than a level of the step difference. Accordingly, a post 200 having improved reliability may be formed later as shown in in FIG. 9K.

Although not illustrated, the residue PR3_F may have, for example, various shapes. For example, the residue PR3_F may continue from the sidewall PR3_W of the third photoresist layer, and may have a downwardly curved shape. Even in this case, the level LI of the portion on which surfaces of the residue PR3_F and the second metal seed layer 160b are in contact with each other may be formed to be substantially equal to or lower than the level of the step difference.

Referring to FIG. 9K, the posts 200 may be formed on the second metal seed layer 160b in the third opening OP3 according to FIG. 9J.

The posts 200 may include a material the same as, substantially the same as, or similar to the second metal seed layer 160b, and the posts 200 may be grown from the second metal seed layer 160b on the metal layers 150 using an electrolytic plating method, or the like.

Referring to FIG. 9J, the residue PR3_F separated from a lower portion of the sidewall PR3_W of the third photoresist layer may be formed along the perimeter of the side lower portion of the third opening OP3 (or “side surface 150SS of metal layers”), the influence of the residue PR3_F on the posts 200 may be reduced.

Referring to FIG. 9L, the third photoresist layer PR3 may be removed, and a portion of the second metal seed layer 160b may be removed.

Referring also to FIG. 9K, the third photoresist layer PR3 may be removed through a third stripping process after electrolytic plating for forming the posts 200 is completed.

Accordingly, the second metal seed layer 160b may be exposed on a side surface of the metal layers 150SS, a surface of the upper pads 120U, and an upper surface of the lower redistribution structure 100, and the exposed portion may be removed through etching. Accordingly, the second metal seed layer 160b may only remain between the metal layers 150 and the posts 200.

Accordingly, referring to FIGS. 2 and 9L together, at least a portion 200LS of the lower surface of the plurality of posts may be exposed to oppose (for example, face) the upper surface 120US_1 of an edge of the upper pad. Also, a lower surface 200LS of plurality of posts, a side surface 150SS of metal layers, and an upper surface 120US_1 of an edge of the upper pad may form (for example, define or at least partially define) a first recessed portion R1.

Thereafter, referring to FIG. 1, a second semiconductor process may be performed on the first semiconductor structure formed according to FIGS. 9A to 9L, thereby manufacturing the semiconductor package 1000A. First, the lower chip structure 300 may be mounted on the lower redistribution structure 100, and an encapsulant 400 covering the lower chip structure 300, the upper pad 120U, the metal layers 150, and surrounding the surface of posts 200 on the lower redistribution structure 100 may be formed. Here, the encapsulant 400 may be inserted into the first recessed portion R1, and the encapsulant 400 may be in contact with a side surface of the second metal seed layer 160b and the lower surface 200LS of the plurality of posts in the first recessed portion R1.

Thereafter, the upper redistribution structure 500 may be formed on the encapsulant 400, and in example embodiments, the upper chip structure 600 and the heat dissipation material 700 may be formed on the upper redistribution structure 500 (see FIG. 7).

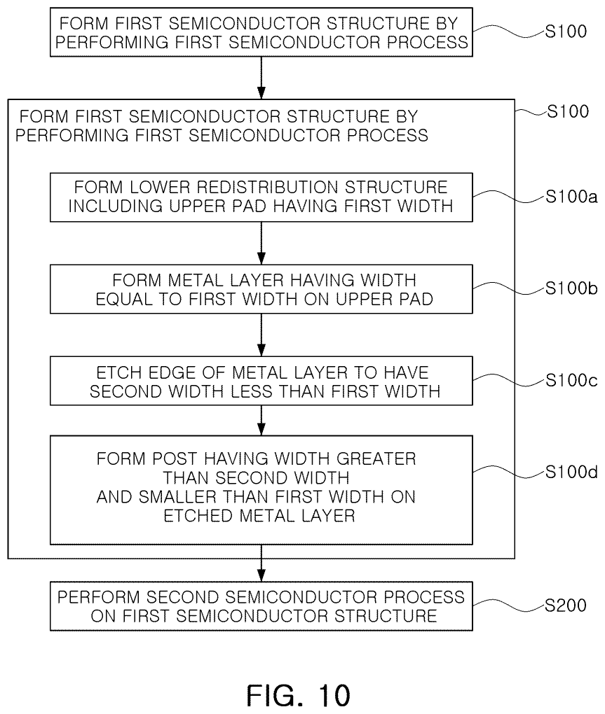

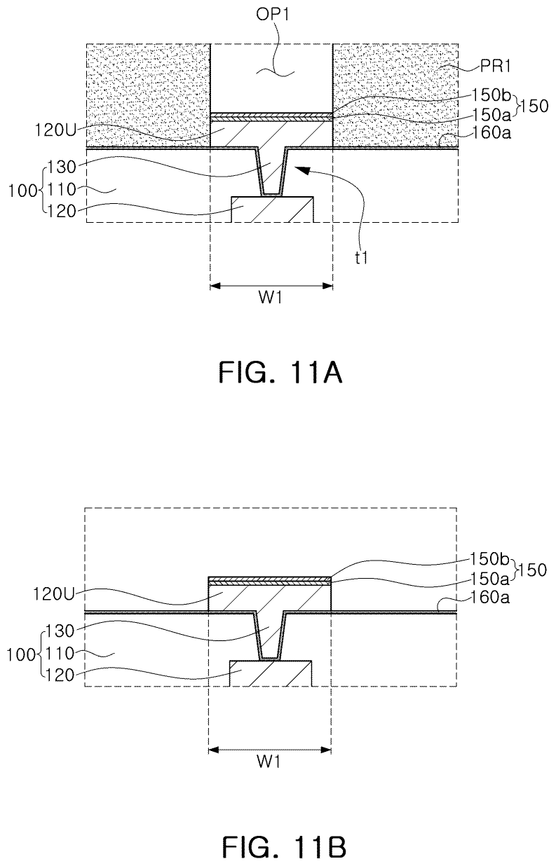

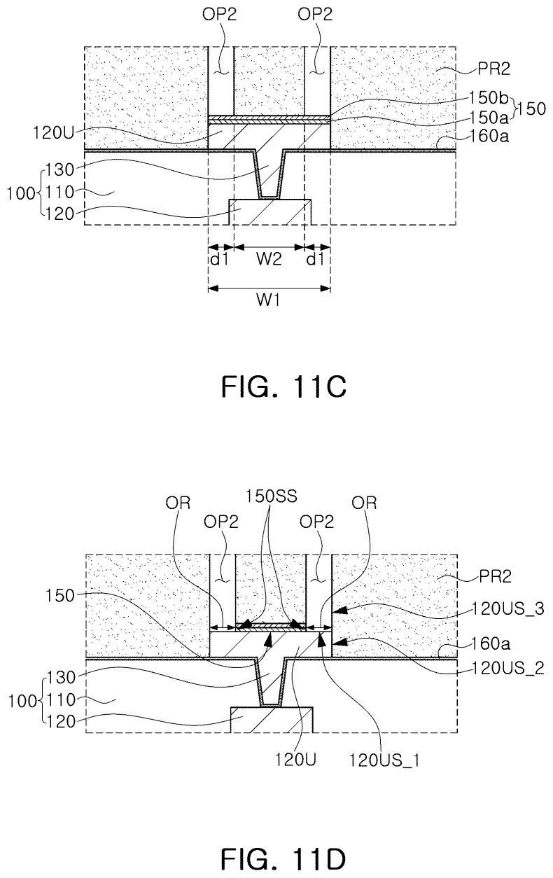

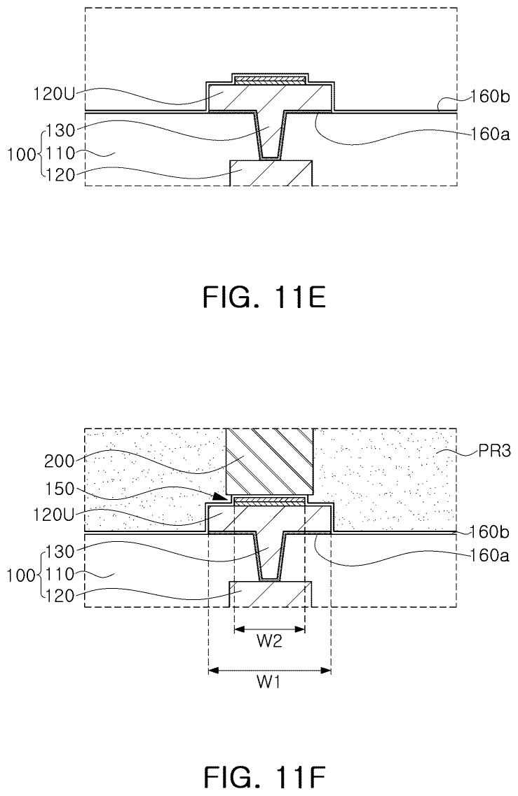

FIG. 10 is a flowchart illustrating processes of a method of manufacturing a semiconductor package 1000A according to some example embodiments. FIGS. 11A to 11F are cross-sectional diagrams illustrating a method of manufacturing a semiconductor package 1000A according to example embodiments. FIGS. 11A to 11F are diagrams continuing from the manufacturing method described with reference to FIGS. 9A to 9C to describe another method of manufacturing the semiconductor package 1000A according to example embodiments.

Referring to, FIGS. 9A to 9C, FIG. 10and FIGS. 11A to 11F, a first semiconductor structure may be formed by performing a first semiconductor process (S100). Thereafter, a semiconductor package 1000A may be formed by performing a second semiconductor process on the first semiconductor structure to form (S200).

Referring to FIGS. 9A to 9C and FIG. 10, a lower redistribution structure 100 including an upper pad 120U having a first width W1 may be formed (S100a).

Referring to FIGS. 10 and 11A to 11B, metal layers 150 having a width equal to the first width W1 may be formed on the upper pad 120U (S100b).

Referring to FIG. 11A, a plurality of metal layers 150 may be formed sequentially on the upper pad 120U in the first opening OP1.

Similar to the example described with reference to FIG. 9F, the plurality of metal layers 150 may include a first metal layer 150a using an electrolytic plating method or an electroless plating method, and a second metal layer 150b on the first metal layer 150a, which may be formed using the same method. For example, the first metal layer 150a may include a metal material including Ni or a Ni alloy, and the second metal layer 150b may include a metal material such as Au or Pd.

Referring back to FIG. 11A, the plurality of metal layers 150 may be formed to have the same width as the upper pad 120U having the first width W1.

Referring to FIG. 11B, similarly to FIG. 9D, the first photoresist layer PRI may be removed.

The first photoresist layer PRI may be removed through the first stripping process. Accordingly, a portion of the surface of the first metal seed layer 160a and a portion of the surface of the upper pad 120U and metal layers 150 may be exposed.

Referring to FIGS. 10 and 11C to 11D, edges of the metal layers 150 may be etched such that the metal layers 150 may have a second width W2 less than the first width (S100c).

Referring to FIG. 11C, after the operation in FIG. 11B, a second photoresist layer PR2 may be formed, and a second opening OP2 exposing an upper surface of the edge of the metal layers 150 may be formed.

The second photoresist layer PR2 may be applied to the partially exposed surfaces of the first metal seed layer 160a, the upper pad 120U, and the metal layers 150 by the first stripping process according to FIG. 11B. The second photoresist layer PR2 may configured the same as or similarly to the second photoresist layer PR2 described with reference to FIG. 9E, and the detailed description thereof will thus not be provided.

A photomask may be aligned on the second photoresist layer PR2, and a second opening OP2 exposing an upper surface of an edge of the metal layers 150 may be formed using the photomask. Referring to FIG. 3 and FIG. 11C together, the second opening OP2 may have a donut shape having an inner portion and an outer portion spaced apart from the inner portion by a uniform distance. Specifically, the inner portion may have a circular shape having a diameter and a second width WI smaller than the first width, and the outer portion may be disposed uniformly spaced apart from the inner portion by a first distance dl. Accordingly, the upper surface of the edge of the metal layers 150 exposed by the second opening OP2 may have the same shape as that of the second opening OP2.

Referring to FIG. 11D, edges of the metal layers 150 exposed by the second opening OP2 may be removed by etching.

Referring to FIG. 11D, the edge of the metal layers 150 exposed by the second opening OP2 may be removed by etching up to the upper surface 120US_1 of the edge of the upper pad such that the upper surface 120US_1 of the edge of the upper pad and the side surface 150SS of the metal layers may be exposed.

Accordingly, an open region OR surrounding the side surface 150SS of the metal layers may be formed on the upper pad 120U. As described with reference to FIG. 2, the open region OR may be defined in a range from the side surface 150SS of the metal layers to the virtual side surface 120US_3 connecting (for example, extending from) the side surface 120US_2 of the upper pad in the vertical direction (Z-direction).

Referring to FIGS. 10 and 11E to 11F, a post 200 having a width greater than the second width W2 and smaller than the first width W1 may be formed on the etched metal layer (S100d).

Referring to FIG. 11E, the second photoresist layer PR2 may be removed (see FIG. 9G) and a second metal seed layer 160b may be formed (FIG. 9H) in the same way as or similarly to the example described with reference to FIGS. 9G and 9H.

Referring to FIG. 11F, in the same way as or similarly to the example described with reference to FIGS. 91 to 9K, a third photoresist layer PR3 may be formed on the second metal seed layer 160b, a photomask may be aligned on the third photoresist layer PR3, a third opening OP3 having a width greater than the second width W2 and smaller than the first width W1 may be formed by performing exposure and development processes using the photomask (see FIGS. 9I and 9J), and posts 200 may be formed in the third opening OP3 (see FIG. 9K). Thereafter, although not illustrated, the third photoresist layer PR3 may be removed and a portion of the second metal seed layer 160b may be removed.

Thereafter, a second semiconductor process may be performed on the first semiconductor structure formed according to FIGS. 9A to 9C and 11A to 11F, thereby manufacturing the semiconductor package 1000A. As described above, the lower chip structure 300 may be mounted on the lower redistribution structure 100, and an encapsulant 400 covering the lower chip structure 300 on the lower redistribution structure 100 and surrounding surfaces of the upper pad 120U, the metal layers 150, and the posts 200 may be formed. Here, the encapsulant 400 may be inserted into the first recessed portion R1, and the encapsulant 400 may be in contact with a side surface of the second metal seed layer 160b and the lower surface 200LS of the plurality of posts in the first recessed portion R1.

Thereafter, an upper redistribution structure 500 may be formed on the encapsulant 400, and in example embodiments, an upper chip structure 600 and a heat dissipation material 700 may be formed on the upper redistribution structure 500 (see FIG. 7).

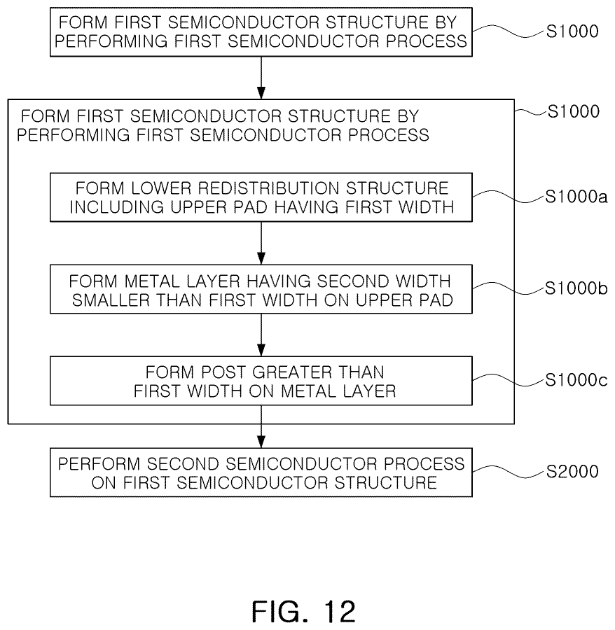

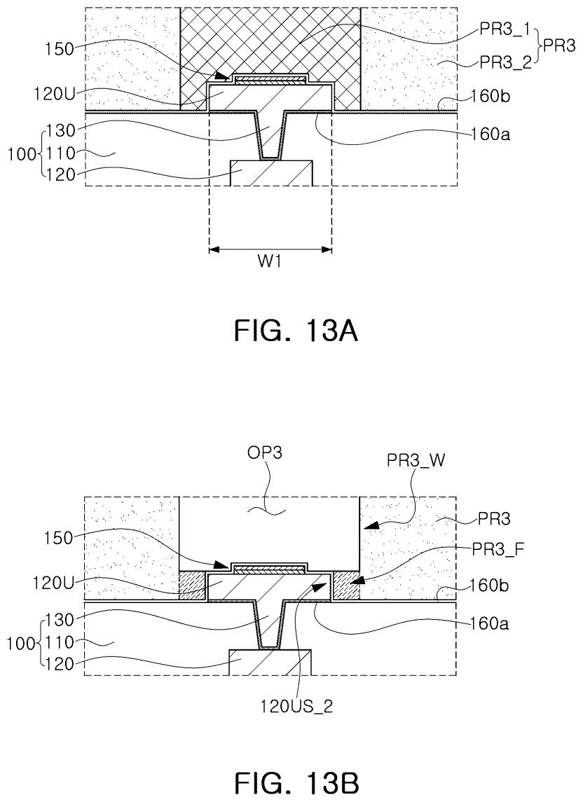

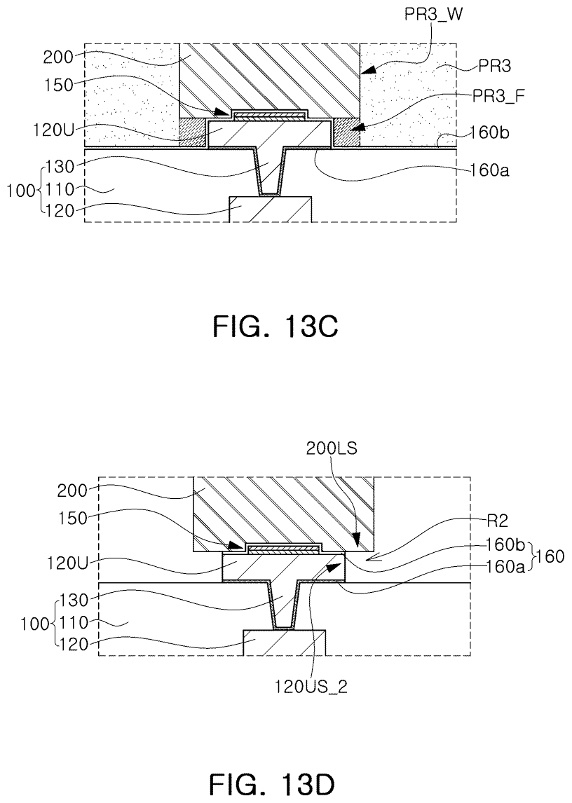

FIG. 12 is a flowchart illustrating processes of a method of manufacturing a semiconductor package 1000B in order according to some example embodiments. FIGS. 13A to 13D are cross-sectional diagrams illustrating a method of manufacturing a semiconductor package 1000B in order according to example embodiments. FIGS. 13A to 13D are diagrams continuing from the manufacturing method described with reference to FIGS. 9A to 9H to describe a method of manufacturing the semiconductor package 1000B according to example embodiments.

Referring to FIG. 12, and FIGS. 9A to 9H, and FIGS. 12A to 12D, a first semiconductor structure may be formed by performing a first semiconductor process (S1000). Thereafter, a semiconductor package 1000B may be formed by performing a second semiconductor process on the first semiconductor structure (S2000).

Referring to FIG. 12 and FIGS. 9A to 9D, a lower redistribution structure 100 including an upper pad 120U having a first width W1 may be formed (S1000a).

Referring to FIGS. 12 and 9E to 9G, metal layers 150 having a second width W2 smaller than the first width may be formed on the upper pad 120U (S1000B).

Referring to FIGS. 12, 9H, and 13A to 13D, posts 200 having a width greater than the second width W2 and smaller than the first width W1 may be formed on the metal layers 150 (S1000C).

Referring to FIG. 13A, similarly to FIG. 9I, a third photoresist layer PR3 may be formed on the second metal seed layer 160b. Thereafter, to form the third opening OP3, an exposure process may be performed on a predetermined or, alternatively, a desired portion by aligning the photomask on the third photoresist layer PR3.

Using the photomask, an exposure process may be performed only on a portion PR3_2 (or “photosensitive portion”) of the third photoresist layer PR3 other than a portion PR3_1 (or “non-photosensitive portion”) to form a third opening OP3, and during a development process thereafter, by removing the non-photoresistive portion PR3_1, the third opening OP3 may be formed (see FIG. 13B). Here, the non-photoresistive portion PR3_1 may have a width greater than the first width W1.

Referring to FIG. 13B, the third opening OP3 may be formed by developing and removing the non-photoresistive portion PR3_1 according to FIG. 13A.

The third opening OP3 may be formed to have a width greater than the first width W1 of the upper pad 120U. Accordingly, at least a portion of the upper surface 100 of the lower redistribution structure may be exposed by the third opening OP3.

Here, a lower portion of the sidewall PR3_W of the third photoresist layer may be distanced from the photomask, such that a degree of curing thereof may be low. Accordingly, residue PR3_F may be separated from the lower portion and may be formed along the perimeter of a side lower portion of the third opening OP3 (or “side surface 120US_2 of the upper pads”).

The residue PR3_F may be formed in a step difference portion formed between the upper pad 120U and the lower redistribution structure 100 by forming a third opening OP3 having a width greater than the first width W1. The residue PR3_F may be in contact with a surface of the second metal seed layer 160b in the step difference portion. A level of the portion in contact with the surface of residue PR3_F and the second metal seed layer 160b may be formed to be substantially the same as or lower than a level of the step difference. Accordingly, a post 200 having improved reliability may be formed later in FIG. 13C.

Referring to FIG. 13C, the posts 200 may be formed on the second metal seed layer 160b in the third opening OP3 according to FIG. 13B.

Referring to FIG. 13B, the residue PR3_F separated from the lower portion of the sidewall PR3_W of the third photoresist layer is formed along the perimeter of the side lower portion of the third opening OP3 (or “side surface 120US_2 of the upper pads”), influence of the residue PR3_F on the posts 200 may be reduced.

Referring to FIG. 13D, the third photoresist layer PR3 may be removed, and a portion of the second metal seed layer 160b may be removed.

Referring to FIG. 9K together, the third photoresist layer PR3 may be removed through a third stripping process after electrolytic plating for forming the posts 200 is completed.

Accordingly, the second metal seed layer 160b may be exposed on a side surface 120US_2 of the upper pads, and an upper surface of the lower redistribution structure 100, and the exposed portion may be removed through etching. Accordingly, the second metal seed layer 160b may only remain between the upper pads 120U and the posts 200.

Accordingly, at least a portion 200LS of the lower surface of the plurality of posts may be exposed to oppose (for example, face) at least a portion of the upper surface of the lower redistribution structure 100. Also, the lower surface 200LS of the plurality of posts, the side surface 120US_2 of the upper pads, and at least a portion of the upper surface of the lower redistribution structure 100 may form (for example, define or at least partially define) a second recessed portion R2.

Thereafter, referring to FIG. 4 together, a semiconductor package 1000B may be manufactured by performing a second semiconductor process on the first semiconductor structure formed according to FIGS. 9A to 9H and FIGS. 13A to 13D. First, the lower chip structure 300 may be mounted on the lower redistribution structure 100, and an encapsulant 400 covering the lower chip structure 300 on the lower redistribution structure 100, and surrounding surfaces of the upper pad 120U, the metal layers 150, and the surface of posts 200. Here, the encapsulant 400 may be inserted into the second recessed portion R2, and the encapsulant 400 may be in contact with a side surface of the second metal seed layer 160b and the lower surface 200LS of the plurality of posts in the second recessed portion R2.

Thereafter, a upper redistribution structure 500 may be formed on the encapsulant 400, and in example embodiments, an upper chip structure 600 and a heat dissipation material 700 may be formed on the upper redistribution structure 500 (see FIG. 7).

According to the aforementioned example embodiments, a semiconductor package having improved reliability may be provided.

While some example embodiments have been illustrated and described above, it will be apparent to those ordinarily skilled in the art that modifications and variations could be made without departing from the spirit and scope of inventive concepts as in the appended claims.

What is claimed is:

1. A semiconductor package, comprising:
a first redistribution structure including upper pads;
a semiconductor chip on the first redistribution structure;
an encapsulant on the first redistribution structure and surrounding the semiconductor chip;
a second redistribution structure on the encapsulant and including an upper redistribution layer;
a plurality of posts penetrating the encapsulant and electrically connecting the upper pads of the first redistribution structure to the upper redistribution layer of the second redistribution structure;
a metal layer between the upper pads and the plurality of posts and having an upper surface having a first step difference with an upper surface of an edge of the upper pads; and
a seed layer between the metal layer and the plurality of posts.

2. The semiconductor package of claim 1, wherein a horizontal width of ones of the plurality of posts is greater than a horizontal width of the metal layer.

3. The semiconductor package of claim 1, wherein a horizontal width of the upper surface of an edge of the upper pads is 2 um or more and 4 um or less.

4. The semiconductor package of claim 1,
wherein a horizontal width of ones of the plurality of posts is greater than a horizontal width of the metal layer,
a horizontal width of ones of the plurality of posts is smaller than a horizontal width of the upper pads, and
at least a portion of a lower surface of the plurality of posts is exposed to oppose at least a portion of the upper surface of an edge of the upper pad.

5. The semiconductor package of claim 4,
wherein the lower surface of the plurality of posts, a side surface of the metal layer, and the upper surface of an edge of the upper pad define a first recessed portion recessed in a direction toward a center of the metal layer when viewed in a cross-sectional view, and
at least a portion of the encapsulant is in the first recessed portion.

6. The semiconductor package of claim 5, wherein the encapsulant contacts the lower surface of an edge of the plurality of posts in the first recessed portion.

7. The semiconductor package of claim 1,
wherein an upper surface of the upper pads has a second step difference with the first redistribution structure,
the seed layer extends to cover a side surface of the metal layer and the upper surface of an edge of the upper pads,
a horizontal width of ones of the plurality of posts is greater than a horizontal width of the upper pads, and
at least a portion of a lower surface of the plurality of posts is exposed to oppose at least a portion of an upper surface of the first redistribution structure.

8. The semiconductor package of claim 7, wherein a horizontal width of the lower surface of the plurality of posts is 2 um or more and 4 um or less.

9. The semiconductor package of claim 7,
wherein the lower surface of the plurality of posts, a side surface of the upper pads, and the upper surface of the first redistribution structure define a second recessed portion recessed in a direction toward a center of the upper pad when viewed in a cross-sectional view, and
at least a portion of the encapsulant is in the second recessed portion.

10. A semiconductor package, comprising:
a first redistribution structure including upper pads;
a semiconductor chip on the first redistribution structure;
an encapsulant on the first redistribution structure and surrounding the semiconductor chip;
a second redistribution structure on the encapsulant and including an upper redistribution layer;
a plurality of posts penetrating the encapsulant and electrically connecting the upper pads of the first redistribution structure to the upper redistribution layer of the second redistribution structure; and
a metal layer between the upper pads and the plurality of posts and exposing an upper surface of an edge of the upper pads and a lower surface of an edge of the plurality of posts.

11. The semiconductor package of claim 10,
wherein, a side surface of the plurality of posts protrudes further than a side surface of the metal layer when viewed in a cross-sectional view,
the semiconductor package defines a first groove portion recessed in a direction toward a center of the metal layer along a side surface of the metal layer between the plurality of posts and the upper pads, and
the encapsulant is in the first groove portion.

12. The semiconductor package of claim 11, wherein the encapsulant has a portion below the plurality of posts in the first groove portion.

13. The semiconductor package of claim 10,
wherein a side surface of the plurality of posts protrudes further than a side surface of the upper pads when viewed in a cross-sectional view,
the semiconductor package defines a second groove portion recessed in a direction toward a center of the upper pads along a side surface of the upper pads between ones of plurality of posts and the upper surface of the first redistribution structure, and
the encapsulant is in the second groove portion.

14. A method of manufacturing a semiconductor package, the method comprising:
forming a first redistribution structure including an upper pad having a first width;
forming a metal layer on the upper pad, the metal layer having a second width smaller than the first width;
forming a post on the metal layer, the post having a width greater than the second width;
forming a semiconductor chip on the first redistribution structure, the semiconductor chip electrically connected to at least a portion of the upper pad;
forming an encapsulant on the first redistribution structure, the encapsulant at least partially surrounding the semiconductor chip and the post; and
forming a second redistribution structure on the encapsulant.

15. The method of claim 14, wherein the forming the metal layer on the upper pad includes:
forming a first photoresist layer on the first redistribution structure, the first photoresist layer at least partially covering the upper pad;
forming a first opening, the first opening penetrating the first photoresist layer, exposing a portion of an upper surface of the upper pad, and having a second width less than the first width;
in the first opening, forming a metal layer on the upper pad; and
removing the first photoresist layer.

16. The method of claim 14, wherein the forming the post on the metal layer includes:
forming a metal seed layer on the first redistribution structure, the metal seed layer at least partially covering surfaces of the upper pad and the metal layer;
forming a second photoresist layer covering the metal seed layer;
forming a second opening on the upper pad, the second opening penetrating the second photoresist layer and exposing a portion of the metal seed layer;
in the second opening, forming the post on an upper surface of the metal layer, the post having a width greater than the second width on the metal seed layer;
removing the second photoresist layer; and
removing a partially exposed portion of the metal seed layer by removing the second photoresist layer.

17. The method of claim 16, wherein, in the forming the second opening, a
residue of the second photoresist layer remains on the upper pad in the second opening,
the residue is located at below a first metal seed layer, the first metal seed layer covering an upper surface of the metal layer, and
the residue contacts a portion of a second metal seed layer, the second metal seed layer covering a side surface of the metal layer on the upper pad.

18. The method of claim 14, wherein the forming the metal layer includes:
forming the metal layer on the upper pad, the metal layer having a width equal to the
first width;
forming a first photoresist layer on the first redistribution structure, the first photoresist layer at least partially covering surfaces of the upper pad and the metal layer;
forming a first opening, the first opening penetrating the first photoresist layer and exposing an upper surface of an edge of the metal layer;
in the first opening, exposing an upper surface of an edge of the upper pad by removing the upper surface of an edge of the metal layer; and
removing the first photoresist layer.

19. The method of claim 18,
wherein the first opening has an annular shape having an inner portion and an outer portion,
the inner portion has a circular shape having a diameter of the second width,
the outer portion is uniformly spaced apart from the inner portion by a first distance, and
the first distance is 2 μm to 4 μm.

20. The method of claim 14, wherein the forming the post on the metal layer includes:
forming a metal seed layer on the first redistribution structure, the metal seed layer at least partially covering surfaces of the upper pad and the metal layer;
forming a first photoresist layer, the first photoresist layer at least partially covering the metal seed layer;
forming a second opening to expose the metal seed layer, the second opening penetrating the first photoresist layer and having a width greater than the first width, the metal seed layer at least partially surrounding surfaces of the upper pad and the metal layer;
in the second opening, forming the post on a surface of the metal seed layer
removing the first photoresist layer; and
removing a partially exposed portion of the metal seed layer by removing the first photoresist layer.
